(19) United States
(12) Patent Application Publication
(10) Pub. No.: US 2026/0060080 A1
(43) Pub. Date: Feb. 26, 2026

(54) Aluminum Nitride Bonding Layer

(71) Applicant: Applied Materials, Inc., Santa Clara, CA (US)

(72) Inventors: Yoocharn JEON, Palo Alto, CA (US); Michel EL KHOURY MAROUN, Palo Alto, CA (US)

(21) Appl. No.: 18/812,242

(22) Filed: Aug. 22, 2024

(51) Int. Cl. H01L 23/373; H01L 21/02; H01L 21/20; H01L 23/14

(52) U.S. Cl. CPC H01L 23/3738; H01L 21/02019; H01L 21/2007; H01L 23/147

(57) ABSTRACT

Methods and structures relating to bonding wafers using an aluminum nitride bonding layer. In some embodiments, the method may comprise forming a bonding layer of aluminum nitride on a first wafer where the aluminum nitride is grown epitaxially onto the first wafer and bonding the first wafer to a second wafer or die using a low temperature bonding process of less than 400 degrees Celsius. The aluminum nitride may be epitaxially grown using a physical vapor deposition (PVD) process, a metal organic chemical vapor deposition (MOCVD) process, or a molecular-beam epitaxy (MBE) process. The carrier wafer may be silicon with a (111) crystal structure orientation or 4H-silicon carbide with a (001) crystal structure orientation at the interface with the bonding layer.

### FIELD

Embodiments of the present principles generally relate to semiconductor processing of semiconductor substrates.

### BACKGROUND

Semiconductor devices are formed on wafers called device wafers. The device wafers may incorporate back side power delivery networks (BSPDN) and other designs that require heat generated by the operation of the semiconductor devices to be removed to maintain performance of the devices. In such cases, a carrier wafer or heat spreader may be applied to the device wafer to allow dissipation of the heat into the heat spreader. The inventors have observed, however, that if a bonding layer is used between the device wafer and the carrier wafer to strengthen the bond, the bonding layer substantially lowers the thermal conductivity of the thermal path from the devices to the heat spreader, resulting in higher device temperatures and higher device /fer/ bonding layer interface temperatures.

Accordingly, the inventors have provided methods and structures that improve the thermal performance characteristics of a bonding layer between the device wafer and the carrier wafer.

### SUMMARY

Methods and structures that improve the thermal performance characteristics of bonding layers are provided herein.

In some embodiments, a method for bonding may comprise obtaining a first wafer where the first wafer comprises a silicon-based material and forming a bonding layer comprising aluminum nitride on the first wafer where the bonding layer comprising aluminum nitride is grown epitaxially onto the first wafer.

In some embodiments, the method may further include a bonding layer comprising aluminum nitride that is epitaxially grown using a physical vapor deposition (PVD) process, a metal organic chemical vapor deposition (MOCVD) process, or a molecular-beam epitaxy (MBE) process, a first wafer that is silicon with a (111) crystal structure orientation at an uppermost surface on which the bonding layer comprising aluminum nitride is formed, a first wafer that is 4H-silicon carbide with a (001) crystal structure orientation at an uppermost surface on which the bonding layer comprising aluminum nitride is formed, a plasma clean process that is performed on the first wafer prior to forming the bonding layer comprising aluminum nitride on the first wafer, a plasma clean process that is a hydrofluoric acid-based clean process or a dry etching process, a bonding layer comprising aluminum nitride on the first wafer that is substantially formed of an epitaxial aluminum nitride, a bonding layer comprising aluminum nitride that has a thickness of approximately 100 nanometers to approximately 10 micrometers, an aluminum deposition clean process that is performed on the first wafer prior to forming the bonding layer comprising aluminum nitride, forming the bonding layer comprising aluminum nitride which includes alternating a reagent gas between an ammonia gas and a nitrogen gas, a first wafer that is a heat spreader, bonding the first wafer to a second wafer or a die, via the bonding layer comprising aluminum nitride, using a low temperature bonding process of less than 400 degrees Celsius, a first wafer that is bonded to the second wafer or die using a hybrid bonding process, and/or a first wafer that is bonded to the second wafer or die using a fusion bonding process.

In some embodiments, a heat spreader structure may comprise a heat spreader layer and a bonding layer comprising aluminum nitride on the heat spreader layer where the bonding layer comprising aluminum nitride is substantially formed of an epitaxial aluminum nitride.

In some embodiments, the heat spreader structure may further comprise a bonding layer comprising aluminum nitride that has a thickness of approximately 100 nanometers to approximately 10 micrometers, a heat spreader layer that is silicon with a (111) crystal structure orientation at an interface between the heat spreader layer and the bonding layer comprising aluminum nitride, a heat spreader layer that is 4H-silicon carbide with a (001) crystal structure orientation at an interface between the heat spreader layer and the bonding layer comprising aluminum nitride, and/or a heat spreader structure that is bonded to a device wafer or die on a surface of the bonding layer comprising aluminum nitride.

In some embodiments, a non-transitory, computer readable medium having instructions stored thereon that, when executed, cause a method for bonding, the method may comprise forming a bonding layer comprising aluminum nitride on a carrier wafer where the bonding layer comprising aluminum nitride is grown epitaxially onto the carrier wafer and bonding the carrier wafer to a device wafer or die using a low temperature bonding process of less than 450 degrees Celsius.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of bonding wafers or wafers to dies in accordance with some embodiments of the present principles.

FIG. 2 depicts an isometric view of a carrier wafer undergoing a preparation process in accordance with some embodiments of the present principles.

FIG. 3 depicts an isometric view of a carrier undergoing a preparation process using an aluminum deposition clean process that forms a thin oxygen-containing aluminum nitride layer on the carrier in accordance with some embodiments of the present principles.

FIG. 4 depicts an isometric view of a formation process of a bonding layer on a carrier wafer in accordance with some embodiments of the present principles.

FIG. 5 depicts an isometric view of a carrier wafer with a bonding layer bonded to a device wafer in accordance with some embodiments of the present principles.

FIG. 6 depicts an isometric view of a bonded wafer and heat dissipation through the device wafer, the bonding layer, and the carrier wafer in accordance with some embodiments of the present principles.

FIG. 7 is a graph depicting the impact of a bonding layer on heat in a device wafer in accordance with some embodiments of the present principles.

FIG. 8 is a graph depicting the impact of defects in bonding layer material on thermal conductivity in accordance with some embodiments of the present principles.

FIG. 9 depicts an isometric view of a carrier wafer with a bonding layer bonded to a die in accordance with some embodiments of the present principles.

FIG. 10 depicts a cross-sectional view of a device wafer or a die with a surface prepared for bonding with an aluminum nitride layer in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and structures provide improved thermal performance of the interface or bonding layer between a first wafer and a second wafer such as a carrier wafer and a device wafer or between a wafer and a die such as a carrier wafer and one or more dies and the like. The techniques allow for elimination of the traditional low thermal performance interface between wafers and between wafers and dies by forming a bonding layer with improved crystal nucleation. The improved crystal nucleation increases the bulk thermal conductivity of the interface due to the minimization of the scattering at the grain boundaries. The reduced scattering is achieved by growing an aluminum nitride bonding layer epitaxially on the carrier wafer and then bonding the carrier wafer to the device wafer or die. Heat dissipation from the device wafer or die through the bonding layer is substantially improved by the increased thermal conduction. Advantageously, the surface roughness is also reduced by the alignment of the crystal orientation to the carrier wafer, which simplifies the bonding layer formation process on the carrier wafer. Another benefit of the present techniques is that the process enables high temperature epitaxial growth (e.g., 800 degrees Celsius or higher) to form a high-quality crystal structure for the bonding layer material on the carrier wafer instead of the device wafer or die. As such, the devices on the device wafer or die are not subjected to high temperatures, and the bonding of the device wafer or die to the carrier wafer can occur at much lower temperatures (e.g., 400 degrees or less).

Traditionally, electrically insulating bonding layers are formed on the device wafer or die using processes that result in low thermal conductivity materials which inhibit heat removal from the devices on the device wafer or die, leading to higher device temperatures. The inventors have found that when conventional aluminum nitride is used as a bonding layer, the conventional aluminum nitride yields a low thermal conductivity interface layer due to poor nucleation of the crystalline phase. Additionally, conventional aluminum nitride as a bonding layer causes the bonding surface to become rough due to the random nucleation orientation, decreasing bonding strength. Formation of the aluminum nitride on the device wafer or die also must be performed at 400 degrees Celsius or less to protect the devices on the device wafer. The rough surfaces and low thermal conductivity of the conventional aluminum nitride substantially inhibit the heat dissipation from the device wafer or die into the carrier wafer (when the carrier wafer functions as a heat spreader for the devices on the device wafer or die).

The present techniques overcome the aforementioned problems by forming the bonding layer on the carrier wafer instead of the device wafer or die. In some embodiments, the carrier wafer acts as a heat spreader and does not have heat sensitive device structures with low thermal budgets which allows the carrier wafer to be subjected to much higher process temperatures than the device wafer or die. In addition, in the present techniques, the bonding layer is formed of epitaxially grown aluminum nitride instead of conventional aluminum nitride. The epitaxial aluminum nitride can be grown at high temperatures (e.g., 750 degrees Celsius or greater) to improve the crystal grain growth without the restraints of forming the bonding layer on the device wafer or die, increasing the thermal conductivity of the epitaxial aluminum nitride and reducing surface roughness. The inventors have found that to grow the epitaxial aluminum nitride with improved nucleation, the growth surface of the carrier wafer should be a silicon-based material with a given crystal structure orientation. For example, but not limited to, the carrier wafer can be a silicon (Si) material with a crystal structure orientation on the growth surface of (111) or a 4H-silicon carbide (4H-SiC) material with a crystal structure orientation on the growth surface of (011) and the like.

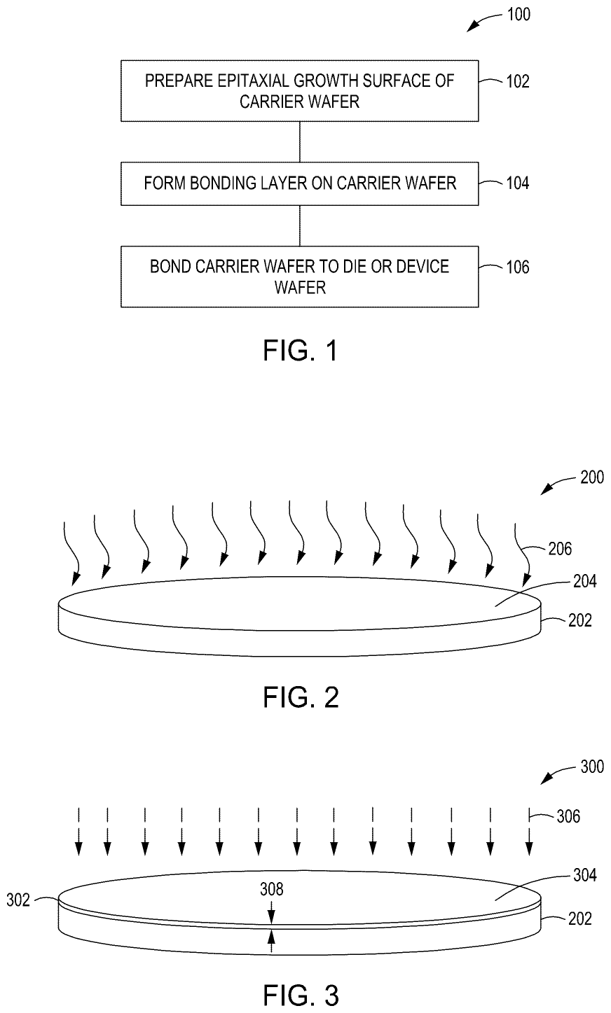

As used herein, a carrier wafer is a silicon-based wafer that may be used to provide support for a device wafer and/or as a heat spreader for devices on the device wafer or die. The carrier wafer, in some embodiments, may have no metallization or some amount of metallization. The bonding techniques of the present principles are not limited to only bonding device wafers or dies to carrier wafers. The techniques are equally applicable to bonding of other types of wafers and the like and even to singulated device chips and heat sinks and the like. A device wafer, die, and a carrier wafer are used only for the sake of brevity in the following examples. FIG. 1 is a method 100 for wafer-to-wafer bonding such as, but not limited to, a device wafer and a carrier wafer and/or for wafer-to-die bonding such as a carrier wafer to a die and the like. In order to promote epitaxial growth of aluminum nitride on the carrier wafer, the carrier wafer may be a Si material with a crystal structure orientation on the bonding surface of (111) or a 4H-SiC material with a crystal structure orientation on the bonding surface of (001) and the like.

In block 102, an epitaxial growth surface 204 of a first wafer or carrier wafer 202 is prepared for forming a bonding layer as depicted in a view 200 of FIG. 2. As the carrier wafer 202 is a silicon-based material, the epitaxial growth surface 204 is prone to oxidation when exposed to the atmosphere. The resulting oxide is amorphous and inhibits epitaxial growth. The oxide may be removed to enhance the formation of the bonding layer. If the carrier wafer 202 is maintained in an oxygen free environment without contamination and/or oxidation of the bonding surface (or if certain bonding layer formation techniques are used, discussed below), the bonding surface preparation may not be performed. A pre-deposition clean process 206 may be performed to prepare the epitaxial growth surface 204 to improve the epitaxial nucleation on the epitaxial growth surface 204. The pre-deposition clean process 206 may be a plasma etching process (dry etch process), a plasma sputtering process, and/or a hydrogen fluoride-based process (e.g., wet etch process using hydrofluoric acid-based process, etc.) and the like. To promote epitaxial growth, the pre-deposition clean process 206 should preserve the underlying crystal structure of the carrier wafer 202 and not roughen or damage the crystal structure of the epitaxial growth surface 204. A plasma sputtering process can be used but care must be taken to avoid crystal structure damage to the carrier wafer. In general, the hydrogen fluoride-based process is more controllable and produces less surface damage.

In the alternative, the epitaxial growth surface 204 may be prepared by removing the oxide and/or contaminants with an aluminum deposition clean process 306 that includes depositing aluminum which then reacts with and forms a thin oxygen-containing aluminum nitride layer 302 on the epitaxial growth surface 204 as depicted in a view 300 of FIG. 3. Aluminum has a higher affinity to oxygen than silicon. The deposition of aluminum reduces, for example, silicon dioxide on the epitaxial growth surface 204 to silicon. In some embodiments, a thickness 308 of the thin oxygen-containing aluminum nitride layer 302 may be from greater than zero to approximately 2 nm. At the completion of the aluminum deposition clean process 306, nitrogen gas can be added into the process to begin the epitaxial growth of aluminum nitride for the formation process of the bonding layer on a surface 304 of the thin oxygen-containing aluminum nitride layer 302.

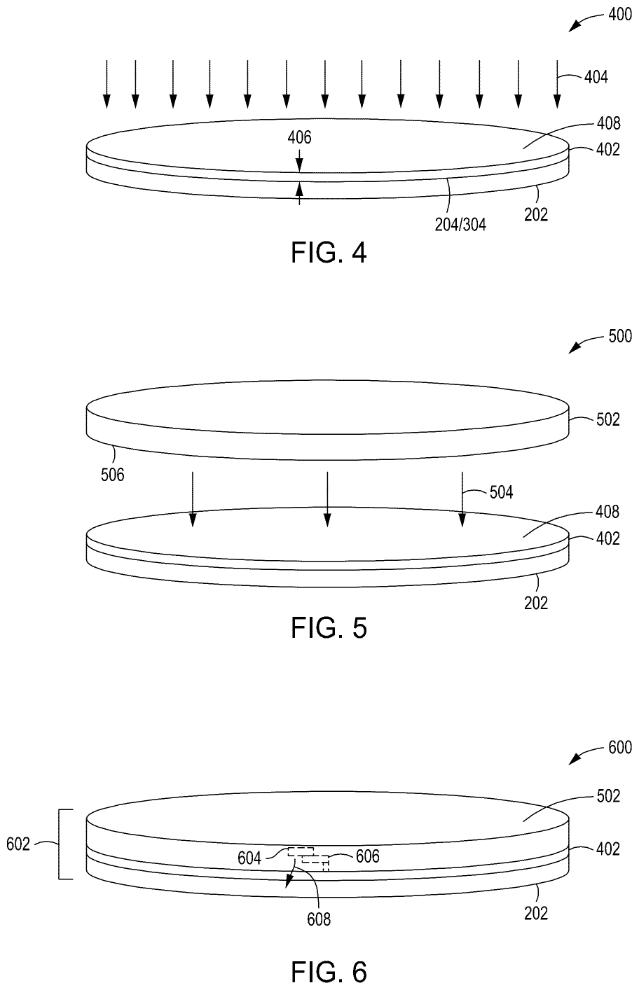

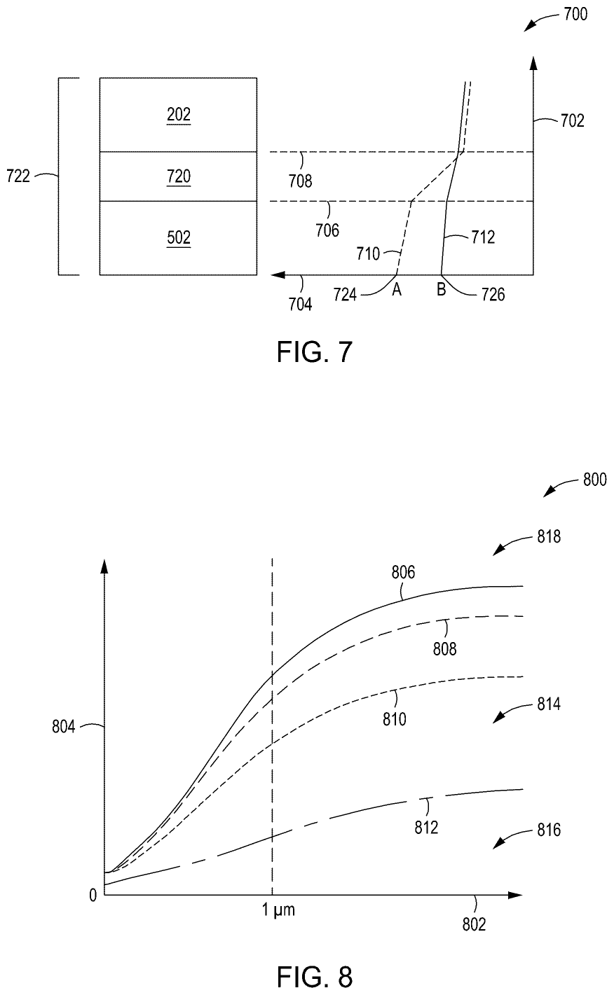

In block 104, a bonding layer 402 is formed by an epitaxial growth process 404 on the epitaxial growth surface 204 (or the surface 304 of the thin oxygen-containing aluminum nitride layer 302 of FIG. 3) of the carrier wafer 202 as depicted in a view 400 of FIG. 4. The epitaxial growth process 404 grows aluminum nitride with a single crystal structure or well-aligned crystallite structures on the carrier wafer 202. Epitaxial growth of aluminum nitride on a silicon-based wafer eliminates the small grain boundaries so that the total crystal structure quality throughout the thickness of the layer will be much higher. A thickness 406 of the bonding layer 402 may be from approximately 100 nanometers to approximately 10 micrometers. A bonding surface 408 is formed by the uppermost surface of the bonding layer 402. In some embodiments, the epitaxial growth process 404 may include a physical vapor deposition (PVD) process, a metal organic chemical vapor deposition (MOCVD) process, and/or a molecular-beam epitaxy (MBE) process and the like. The PVD process is the most economical process with the MOCVD and MBE processes increasing in cost and processing time, respectively. MOCVD produces a higher quality grain growth than PVD while MBE produces the highest quality at the highest expense. The PVD process may also alternate the reagent gas between ammonia gas and nitrogen gas to enhance the crystal quality of the aluminum nitride. In some embodiments, a high temperature process (e.g., a PVD process or an MOCVD process at approximately 750 degrees Celsius or greater) may be used for preparing the epitaxial growth surface of the carrier (block 102), as the high temperature can remove the oxide from the epitaxial growth surface 204 as well as grow epitaxial aluminum nitride on the epitaxial growth surface 204. The present techniques are not limited to the above epitaxial growth processes for aluminum nitride and any other process for producing high quality single crystal or well-aligned crystallite aluminum nitride may be used.

To reduce grain boundaries and increase the quality of the epitaxial aluminum nitride, the epitaxial growth process 404 may be performed at high temperatures (e.g., 600 degrees Celsius to 850 degrees Celsius or more). Higher growth temperatures yield superior grain structures of the aluminum nitride which increases the thermal conductivity of the aluminum nitride. Such high process temperatures are not compatible with the device wafer or dies which have a thermal budget of 400 degrees Celsius or less. The low thermal budget of the device wafer and dies is due to the semiconductor device structures and/or metallization found on the device wafer and dies. The low thermal budget requirement of the device wafer and dies would yield poor crystal quality of epitaxial aluminum nitride at temperatures of 400 degrees Celsius or less. In addition, the device wafer and dies are generally formed of silicon with a crystal orientation of (100) which is an industry standard. High quality single crystal or well-aligned crystallite aluminum nitride cannot be grown epitaxially on silicon with a crystal orientation of (100). Moreover, the device wafer or dies may have various amorphous films deposited on the surface, on which an epitaxial growth is not possible.

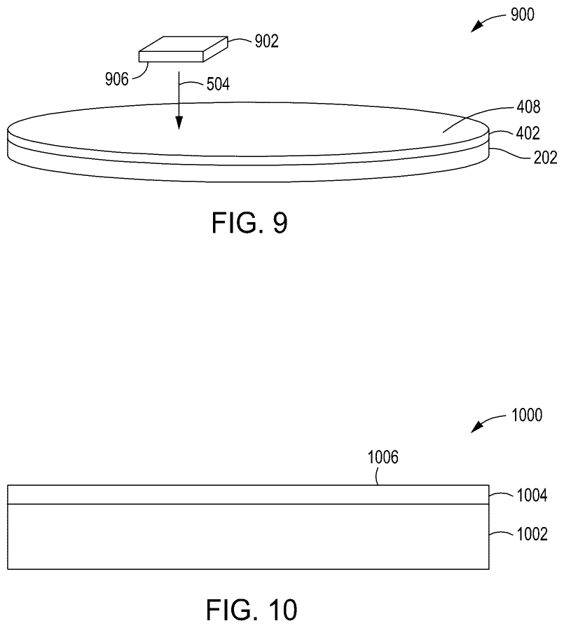

In block 106, the first wafer or carrier wafer 202 is bonded 504 to a bonding surface 506 of a second wafer or device wafer 502 using the bonding layer 402 as depicted in a view 500 of FIG. 5. In some embodiments, the wafer or carrier wafer 202 may be bonded 504 to a bonding surface 906 of a die 902 using the bonding layer 402 as depicted in a view 900 of FIG. 9. The device wafer 502 or die 902 is bonded to the bonding surface 408 of the bonding layer 402. The high-quality crystal structure of the epitaxial aluminum nitride of the bonding layer 402 yields a smoother bonding surface than that of non-epitaxially grown aluminum nitride. The smoother surface produces superior bonding strength between the device wafer 502 or die 902 and the bonding surface 408 of the bonding layer 402. The bonding process can be performed at approximately 400 degrees or less in accordance with the thermal budget constraints of the device wafer 502 or die 902. In some embodiments, the bonding process may be a hybrid bonding process (e.g., mix of metal/dielectric materials, etc.) or a fusion bonding process (e.g., only dielectric materials, etc.).

In some embodiments, a bonding surface 1006 of device wafer or die 1002 may be prepared for bonding with an aluminum nitride layer on the carrier wafer and the like prior to the bonding of block 106 as depicted in a cross-sectional view 1000 of FIG. 10. A bonding assist layer 1004 may be formed on the device wafer or die 1002 comprising, for example, a plasma enhanced chemical vapor deposition (PECVD) silicon carbon nitride (SiCN) layer and/or a physical vapor deposition (PVD) alumina (Al₂O₃) layer and the like. In some instances, SiCN may be used as a diffusion barrier and/or passivation layer for copper present on the device wafer or die 1002. In some embodiments, an Al₂O₃ bonding assist layer may then be formed on the SiCN to obtain a higher bond strength with the aluminum nitride bonding layer on the carrier wafer and the like.

FIG. 6 depicts a view 600 of a bonded wafer 602 that includes the second wafer or device wafer 502 and the first wafer or carrier wafer 202. In some embodiments, the carrier wafer 202 acts as a heat spreader for the devices 604 and metallization 606 of the device wafer 502 (or die 902). Heat 608 dissipates through the device wafer 502 (or die 902), through the bonding layer 402, and into the carrier wafer 202 (heat spreader). The epitaxial aluminum nitride of the bonding layer 402 provides a substantial improvement of thermal conductivity over conventional bonding layer materials. In a graph 700 of a cross-section of a bonded wafer 722 (or die bonded to a wafer), a comparison of the thermal conductivity of a bonding layer 720 with a conventional bonding layer material 710 with low thermal conductivity versus the bonding layer 720 with the bonding layer 402 of the present techniques using epitaxially grown aluminum nitride 712 with high thermal conductivity. The graph 700 depicts a first bonding layer interface 706 between the device wafer 502 or die 902 and the bonding layer 720 and a second bonding layer interface 708 between the bonding layer 720 and the carrier wafer 202 (heat spreader).

The X-axis 702 indicates increasing distance in the up direction away from the heat source (e.g., a device in the device wafer 502 or die 902, etc.), and the Y-axis 704 indicates increasing temperature in the left direction. When heat is dissipated through the device wafer 502 or die 902 and reaches the first bonding layer interface 706, with conventional bonding layer material 710, the low thermal conductivity of the conventional bonding layer material 710 causes an increase in device temperature (point A 724). The high thermal conductivity of the epitaxially grown aluminum nitride 712 of the present techniques allows for more of the heat from the device to dissipate into the carrier wafer 202 (heat spreader) at a faster rate, lowering the device temperature (point B 726) and equalizing the temperature (small temperature drop across the bonding layer 720) of the device and the heat spreader. The quality of the crystal structure of the aluminum nitride also impacts the thermal conductivity of the aluminum nitride material as depicted in a graph 800 of FIG. 8. The X-axis 804 is the thermal conductivity (Wm⁻¹K⁻¹) and the Y-axis 802 is a thickness of the aluminum nitride material.

A first aluminum nitride sample 812 has a large number of defects. The area 816 under the curve represents amorphous and polycrystalline thin films and the like with poor thermal conductivity. The second aluminum nitride sample 810 has 10X less defects than the first aluminum nitride sample 812. The area 814 under the second aluminum nitride sample 810 and above the first aluminum nitride sample 812 represents bulk polycrystalline films. A third aluminum nitride sample 808 has 20× less defects than the second aluminum nitride sample 810. A fourth aluminum nitride sample 806 has zero defects. The area 818 above the fourth aluminum nitride sample 806 represents bulk single crystal or well-aligned crystallite films. Both the thickness and defect level of the aluminum nitride affect the thermal conductivity of an aluminum nitride based bonding layer. As per the graph 800, as the thickness of the film diminishes, the film loses high thermal conductivity. By maintaining a single crystal or well-aligned crystallite structure of the aluminum nitride, a high thermal conductivity level can be maintained despite the thickness of the film. The inventors have found that, in some embodiments, a thickness of approximately 1 μm yields a good tradeoff between thickness and high thermal conductivity for use as a bonding layer. The required thickness is mainly governed by the requirements for specific applications. For thermal management purposes, a minimum thickness is optimal if an application does not have a minimum thickness requirement. Even though the average thermal conductivity of a film increases with the thickness, the total thermal resistance monotonically increases with the thickness.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for bonding, comprising:
obtaining a first wafer, wherein the first wafer comprises a silicon-based material; and
forming a bonding layer comprising aluminum nitride on the first wafer, wherein the bonding layer comprising aluminum nitride is grown epitaxially onto the first wafer.

2. The method of claim 1, wherein the bonding layer comprising aluminum nitride is epitaxially grown using a physical vapor deposition (PVD) process, a metal organic chemical vapor deposition (MOCVD) process, or a molecular-beam epitaxy (MBE) process.

3. The method of claim 1, wherein the first wafer is silicon with a (111) crystal structure orientation at an uppermost surface on which the bonding layer comprising aluminum nitride is formed.

4. The method of claim 1, wherein the first wafer is 4H-silicon carbide with a (001) crystal structure orientation at an uppermost surface on which the bonding layer comprising aluminum nitride is formed.

5. The method of claim 1, wherein a plasma clean process is performed on the first wafer prior to forming the bonding layer comprising aluminum nitride on the first wafer.

6. The method of claim 5, wherein the plasma clean process is a hydrofluoric acid-based clean process or a dry etching process.

7. The method of claim 1, wherein the bonding layer comprising aluminum nitride on the first wafer is substantially formed of an epitaxial aluminum nitride.

8. The method of claim 1, wherein the bonding layer comprising aluminum nitride has a thickness of approximately 100 nanometers to approximately 10 micrometers.

9. The method of claim 1, wherein an aluminum deposition clean process is performed on the first wafer prior to forming the bonding layer comprising aluminum nitride.

10. The method of claim 1, wherein forming the bonding layer comprising aluminum nitride includes alternating a reagent gas between an ammonia gas and a nitrogen gas.

11. The method of claim 1, wherein the first wafer is a heat spreader.

12. The method of claim 1, further comprising:
bonding the first wafer to a second wafer or a die, via the bonding layer comprising aluminum nitride, using a low temperature bonding process of less than 400 degrees Celsius.

13. The method of claim 12, wherein the first wafer is bonded to the second wafer or die using a hybrid bonding process.

14. The method of claim 12, wherein the first wafer is bonded to the second wafer or die using a fusion bonding process.

15. A heat spreader structure, comprising:
a heat spreader layer; and
a bonding layer comprising aluminum nitride on the heat spreader layer, wherein the bonding layer comprising aluminum nitride is substantially formed of an epitaxial aluminum nitride.

16. The heat spreader structure of claim 15, wherein the bonding layer comprising aluminum nitride has a thickness of approximately 100 nanometers to approximately 10 micrometers.

17. The heat spreader structure of claim 15, wherein the heat spreader layer is silicon with a (111) crystal structure orientation at an interface between the heat spreader layer and the bonding layer comprising aluminum nitride.

18. The heat spreader structure of claim 15, wherein the heat spreader layer is 4H-silicon carbide with a (001) crystal structure orientation at an interface between the heat spreader layer and the bonding layer comprising aluminum nitride.

19. The heat spreader structure of claim 15, wherein the heat spreader structure is bonded to a device wafer or die on a surface of the bonding layer comprising aluminum nitride.

20. A non-transitory, computer readable medium having instructions stored thereon that, when executed, cause a method for bonding, the method comprising:
forming a bonding layer comprising aluminum nitride on a carrier wafer, wherein the bonding layer comprising aluminum nitride is grown epitaxially onto the carrier wafer; and
bonding the carrier wafer to a device wafer or die using a low temperature bonding process of less than 450 degrees Celsius.
